(19) United States
(12) Patent Application Publication
(10) Pub. No.: US 2026/0291520 A1
(43) Pub. Date: Sep. 24, 2026

(54) ADAPTING A LOG-LIKELIHOOD RATIO TO A CODEWORD USING A MACHINE LEARNING MODEL

(71) Applicant: MICRON TECHNOLOGY, INC., Boise, ID (US)

(72) Inventors: Phong Sy Nguyen, Livermore, CA (US); Dung Viet Nguyen, San Jose, CA (US)

(21) Appl. No.: 19/083,962

(22) Filed: Mar. 19, 2025

(51) Int. Cl. H03M 13/13; H03M 13/00; G06N 3/084

(52) U.S. Cl. CPC H03M 13/13; H03M 13/611; G06N 3/084

(57) ABSTRACT

A system including a memory device and a processing device, operatively coupled with the memory device, wherein the processing device is configured to perform operations. The processing device performs a read operation on the memory device to determine a codeword. The processing device generates, from the read operation, a set of count values representing respective characteristics associated with the codeword. The processing device provides the set of count values as an input to a log-likelihood ratio (LLR) estimator machine learning (ML) model. The processing device receives an output from the LLR estimator ML model, wherein the output comprises an LLR output corresponding to the codeword. The processing device performs an error correction code (ECC) operation on the codeword using the LLR output.

### TECHNICAL FIELD

Embodiments of the disclosure relate generally to memory sub-systems, and more specifically, relate to a system and method of adapting a log-likelihood ratio (LLR) to a codeword in a memory sub-system using a machine learning (ML) model.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 is a flow diagram of an example method of adapting an LLR to a codeword using an ML model, in accordance with some embodiments of the present disclosure.

FIG. 3 is a block diagram illustrating functional segments of adapting an LLR to a codeword using an ML model, in accordance with some embodiments of the present disclosure.

FIG. 4 is a diagram illustrating an example of the plurality of bins, in accordance with some embodiments of the present disclosure.

FIG. 5 is a block diagram of an example computer system in which embodiments of the present disclosure may operate.

### DETAILED DESCRIPTION

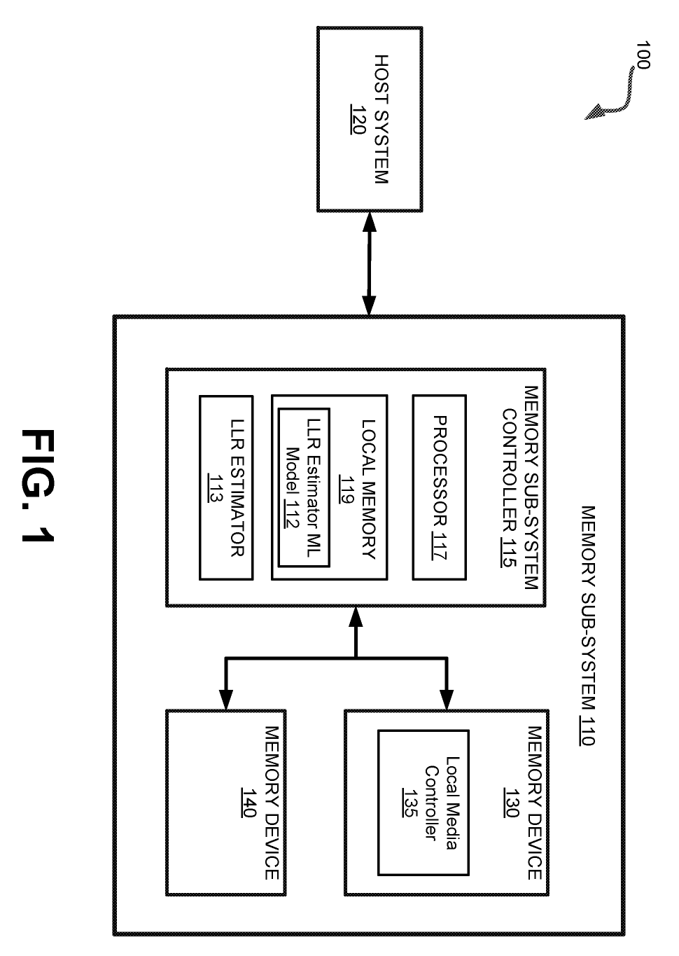

Aspects of the present disclosure are directed to a method of log-likelihood ratio (LLR) adaptation using a machine learning model. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include of one or more planes. For some types of non-volatile memory devices (e.g., NAND devices), each plane includes of a set of physical blocks. Each block includes of a set of pages. Each page includes of a set of memory cells ("cells"). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory cell may be programmed (written to) by applying a certain voltage to the memory cell, which results in an electric charge being held by the memory cell, thus allowing modulation of the voltage distributions produced by the memory cell. A set of memory cells referred to as a memory page may be programmed together in a single operation, e.g., by selecting consecutive bitlines. Precisely controlling the amount of the electric charge stored by the memory cell allows establishing multiple logical levels, thus effectively allowing a single memory cell to store multiple bits of information. A read operation may be performed by comparing the measured threshold voltages (Vt) exhibited by the memory cell to one or more reference voltage levels in order to distinguish between two logical levels for single-level cell (SLCs) and between multiple logical levels for multi-level cells. Each logical level may be translated into a corresponding binary representation of the content of the memory cell

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

One example of a memory sub-system is a solid-state drive (SSD) that includes one or more non-volatile memory devices and a memory sub-system controller to manage the non-volatile memory devices. The memory sub-system controller can encode data into a format for storage at the memory device(s). For example, a class of error detection and correcting codes (ECC), such as low density parity check (LDPC) codes, can be used to encode the data. LDPC codes are capacity-approaching codes, which means that practical constructions exist which allow the error threshold to be set very close to a theoretical maximum. This error threshold defines an upper bound for errors in the data, up to which the probability of lost information can be made as small as desired. LDPC codes are reliable and highly efficient, making them useful in bandwidth-constrained applications. For example, encoded data written to physical memory cells of a memory device can be referred to as a codeword. The data read from the cells, which might include errors and differ from the codeword, can be referred to as a sense word. The sense word can include one or more of user data, error correcting code, metadata, or other information.

In performing error correcting code operations, including, as part of a read operation, encoded data stored on the memory device can be transmitted from the memory device to the memory sub-system controller. The memory sub-system controller can perform decoding operations to decode the encoded data into the original sequence of bits that were encoded for storage on the memory device. A number of bits of the decoded data received by the memory sub-system controller may have been flipped due to noise, interference, distortion, bit synchronization errors, or errors from the media itself (both intrinsic and extrinsic). For example, a bit that may have originally been stored as a 0 may be flipped to a 1 or vice versa.

Many memory sub-systems perform error correcting code operations to attempt to correct bit flip errors in a sense word read from the memory device. For example, a memory sub-system can perform error correcting code operations on stored data to detect and correct errors in the encoded data. In many cases, the data is decoded using an iterative process. Segments of a data array can be decoded to produce a corresponding string of bits (e.g., a sense word).

In LDPC error correction, the log-likelihood ratio (LLR) is a metric used during the decoding process for expressing the confidence level that a particular bit is either a 0 or a 1. The LLR for a bit can be defined as a logarithm of the ratio between the probability that the bit is '0' and the probability that it is '1'. Conventionally, a single, pre-calibrated LLR is applied uniformly across all codewords for a given Read Error Handling (REH) stage. While convenient, this one-size-fits-all approach often proves suboptimal, as different codeword types can exhibit varying threshold distributions, among other characteristics. Threshold distributions represent the likelihood of specific error patterns for a codeword under given conditions, and these can vary significantly between codewords due to factors like physical variations in storage cells, varying noise levels, and operational conditions (e.g., temperature, aging of memory cells). A uniform LLR does not account for these variations, leading to inaccuracies in the decoding process. When a static LLR mismatches the actual probability distribution of errors, the decoder operates with incorrect initial assumptions, which can slow convergence, increase error rates, or result in wasted computational resources.

Because the fixed LLR does not adapt to the specific characteristics of each codeword, the LDPC decoder is less effective in interpreting the soft-bit confidence values, leading to less efficient error correction. This rigidity in the LLR not only limits the decoder’s ability to correct errors but can also degrade the overall reliability and speed of data retrieval in the memory sub-system.

Aspects of the present disclosure address the above and other deficiencies by having a memory sub-system that adjusts an LLR to suit the characteristics for a codeword. Specifically, the system uses a machine learning (ML) model to generate LLRs for each codeword using data retrieved from a read operation. For example, in determining the stored codeword, the system can perform a read operation that returns a hard bit value as a series of hard bits and a series of one or more “soft bits” for each hard bit. The “soft” bit information (alongside hard bit read information (e.g., a hard bit value)) indicates the reliability of a hard value determination (e.g., a confidence level or likelihood that a particular hard bit-value is in fact ‘0’ or ‘1’).

Using the data from the read operation, the system generates a set of count values representing respective characteristics associated with the codeword (e.g., a histogram collection). This set of count values serves as input to a machine learning (ML) model, which in some implementations is a multi-layer neural network. The ML model processes these inputs and produces an adapted LLR (e.g., the “LLR output”), tailored to the specific characteristics of the codeword. Using the LLR output, the system can perform error correction code (ECC) operations, such as low-density parity check (LDPC) decoding, on the codeword.

Advantages of the present disclosure include, but are not limited to a reduction in the codeword error rate in ECC operations (e.g., LDPC). This results in fewer mis-corrected or uncorrected codewords. Beyond yielding a lower trigger rate for error correction, the present disclosure can boost Quality of Service (QoS) by minimizing re-reads or retransmissions and enhance overall reliability for the memory system.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In some embodiments, an LLR estimator ML model 112 is stored in the local memory 119. In some embodiments, the LLR estimator ML model 112 comprises a multi-layer neural network. Alternative embodiments can implement other ML models. Further details are provided below.

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a LLR estimator component 113 that can adapt an LLR to the characteristics of a codeword using an ML model (e.g., LLR estimator ML model 112). In some embodiments, the memory sub-system controller 115 includes at least a portion of the LLR estimator component 113. In some embodiments, the LLR estimator component 113 is part of the host system 120, an application, or an operating system. In other embodiments, local media controller 135 includes at least a portion of LLR estimator component 113 and is configured to perform the functionality described herein.

The LLR estimator component 113 can adjust an LLR to suit the characteristics of a codeword. Specifically, the system uses a machine learning (ML) model to generate individualized LLRs for each codeword using data from the read operation. Using the data from the read operation, the system generates a set of count values representing respective characteristics associated with the codeword (e.g., a histogram collection). This set of count values is provided as an input to an ML model. In some implementations, the system uses a multi-layer neural network as the ML model. From the ML model, the system receives the adjusted LLR as the output. This LLR output is adapted to the characteristics of the codeword. Using the LLR output, the system can perform error correction code (ECC) operations (e.g., low density parity checks (LDPC)) on the codeword.. Further details with regards to the operations of the LLR estimator component 113 are described below.

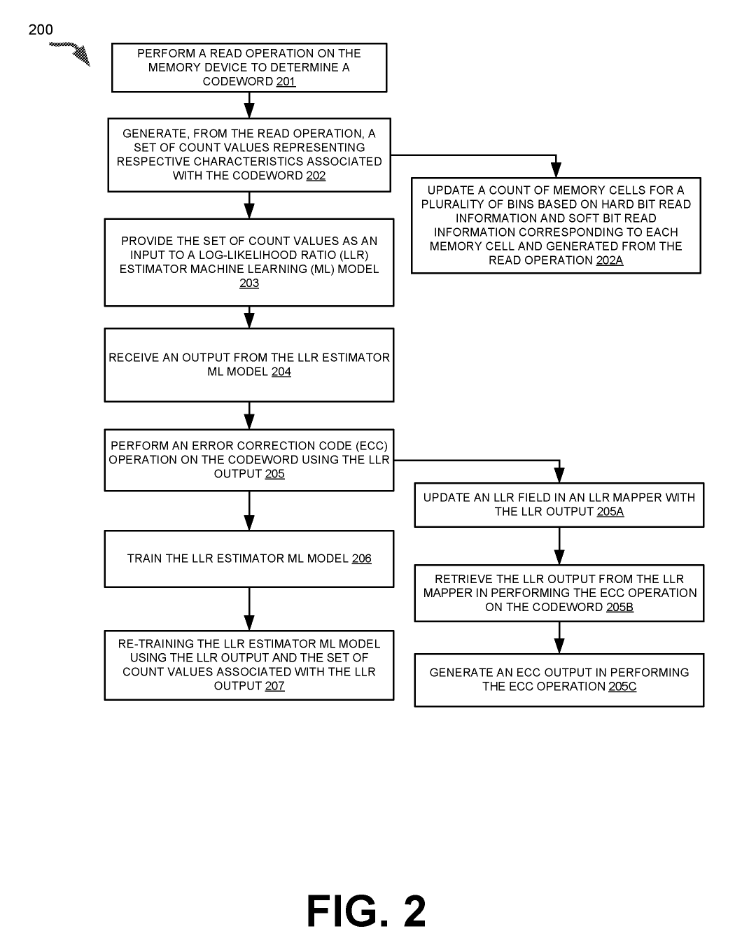

FIG. 2 is a flow diagram of an example method 200 of adapting an LLR to a codeword using an ML model, in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the LLR estimator component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

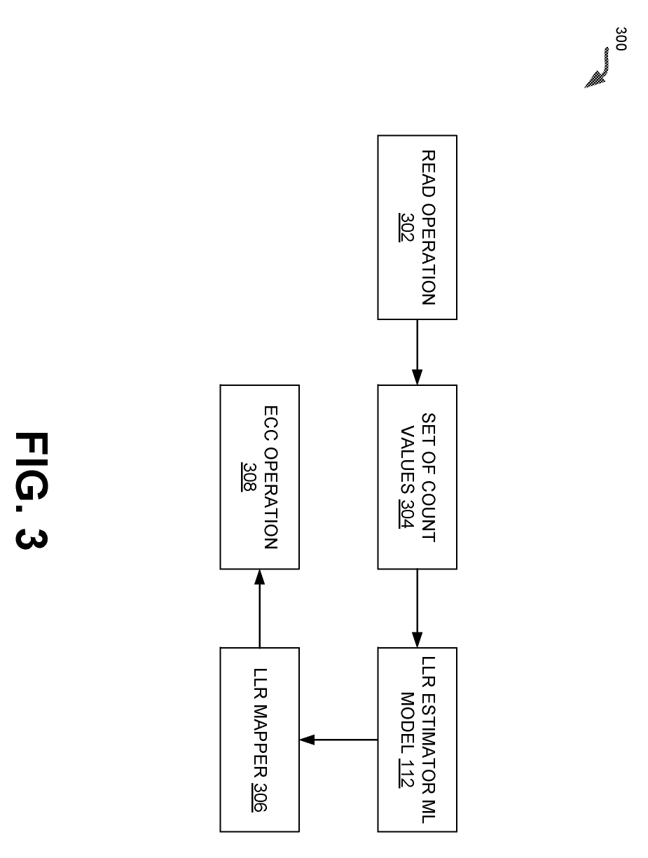

At operation 201, the processing logic (e.g., the LLR estimator component 113) performs a read operation on the memory device to determine a codeword. In some embodiments, the read operation is of a set of read operations to determine the codeword. A codeword is encoded data written to physical memory cells of a memory device, such as memory device 130. In some embodiments, in determining the stored codeword, at operation 201, the processing logic can perform a read operation (e.g., the read operation 302 functional component that is illustrated in FIG. 3) that returns an output. The output can include a hard bit value as a series of hard bits and a series of one or more “soft bits” for each hard bit. The “soft” bit information (alongside hard bit read information (e.g., a hard bit value)) indicates the reliability of a hard value determination (e.g., a confidence level or likelihood that a particular hard bit-value is in fact ‘0’ or ‘1’).

FIG. 3 is a block diagram 300 illustrating functional segments of adapting an LLR to a codeword using an ML model (e.g., LLR estimator ML model 112), in accordance with some embodiments of the present disclosure. These functional segments are segments of the operations performed by processing logic (e.g., the LLR estimator component 113). FIG. 3 illustrates a read operation output 302 received from the read operation performed at operation 201 of FIG. 2, a set of count values 304, an LLR estimator model 112, an LLR mapper 306, and an ECC operation 308. As described with FIG. 1, in some embodiments, the LLR estimator ML model 112 comprises a multi-layer neural network. Alternative embodiments can implement other ML models. Further details are provided below in at least the description of FIG. 2.

Referring again to FIG. 2, at operation 202, the processing logic generates from the read operation 302, a set of count values 304 representing respective characteristics associated with the codeword. This set of count values 304, in some embodiments, is a set of numerical counts that each correspond to specific properties of the memory cells. The characteristics may include a combination of soft bit information (probabilistic confidence levels) and hard bit read information (binary values) associated with each of the memory cells. Each numerical count indicates the number of memory cells that fall into a particular bin, where each bin is defined based on both hard bit and soft bit information of the corresponding memory cells. In some embodiments, the set of count values 304 is in the form of a histogram collection. In some embodiments, at operation 202A, in generating the set of count values 304, the processing logic updates the count of memory cells for each of the plurality of bins based on the hard bit read information and soft bit read information retrieved from the read operation.

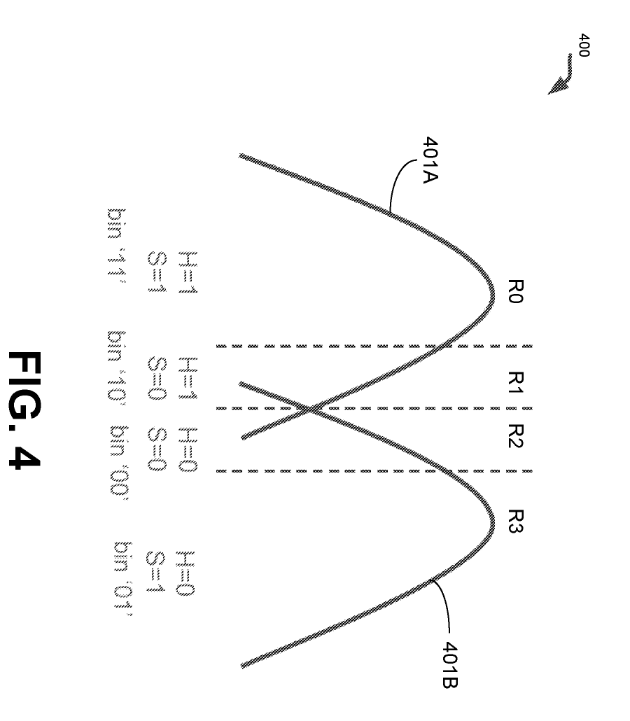

FIG. 4 is a diagram 400 illustrating an example of the plurality of bins, in accordance with some embodiments of the present disclosure. FIG. 4 includes two threshold voltage distributions, 401A and 401B. The threshold voltage distributions are separated into four regions, R0, R1, R2, and R3. Each region is associated with a bin and defined by the hard bit read information and soft bit read information of the memory cells in that region. For example, bin ‘11’ of region R0 is associated with memory cells with a hard bit-value (“H”) of 1 and a soft bit-value (“S”) of 1. In some embodiments, the soft read value of 1 indicates a high confidence level that the hard bit-value of 1 is accurate. In a further example, bin ‘10’ of region R1 is associated with memory cells with a hard bit-value of 1 and a soft read value of 0. In some embodiments, the soft read value of 0 indicates a low confidence level that the hard bit-value of 1 is accurate.

Referring again to FIG. 2, at operation 203, the processing logic provides the set of count values 304 as an input to the LLR estimator ML model 112. In some embodiments, the LLR estimator model comprises a multi-layer neural network. A multi-layer neural network is an artificial neural network architecture comprising multiple layers of interconnected neurons, including an input layer, one or more hidden layers, and an output layer. Each neuron processes input data by applying a weighted sum followed by a non-linear activation function, enabling the network to model complex, non-linear relationships within the data. The inclusion of multiple layers allows the network to learn hierarchical feature representations. In some embodiments of this architecture, a fully connected layer, also known as a dense layer, is implemented. A fully connected layer is where each neuron is connected to every neuron in the preceding layer. Please note that alternative embodiments can implement different ML models other than those described herein. For example, in some embodiments, the LLR estimator ML model 112 can be composed of a single level of linear or non-linear operations, such as an SVM or deep network (i.e., a machine learning model that is composed of multiple levels of non-linear operations), such as a convolutional neural network.

At operation 204, the processing logic receives an output from the LLR estimator ML model 112. In some embodiments, the output comprises an LLR output corresponding to the codeword. The LLR, or log-likelihood ratio, serves as a metric during the decoding process to express the confidence level that a particular bit is either a 0 or a 1. The LLR for a bit can be defined as the logarithm of the ratio between the probability that the bit is '0' and the probability that it is '1'.

At operation 205, the processing logic performs an error correction code (ECC) operation 308 on the codeword using the LLR output. In some embodiments, the ECC operation 308 is a low density parity check (LDPC).

In an embodiment implementing LDPC ECC operations, the LDPC codes leverage the LLR output to enhance their decoding efficiency and accuracy. In the context of LDPC decoding, the LLR output provides soft information about each received bit, representing the logarithm of the probability that a bit is a ‘1’ versus a ‘0’. In some embodiments, this soft information is used for iterative decoding algorithms, such as belief propagation or the sum-product algorithm. During each iteration, the LLR output is exchanged between variable nodes and check nodes, allowing the decoder to progressively refine its estimates of the transmitted bits by combining the likelihoods from different parity-check constraints. After several iterations of exchanging and updating the LLR output between variable nodes and check nodes, the LDPC decoder progressively hones in on the most probable values for each transmitted bit. As the algorithm converges, the LLR output becomes more definitive, allowing the decoder to make hard decisions by selecting the bit value with the higher likelihood for each position in the codeword. Once all parity-check constraints are satisfied, the decoding process is considered successful, and the original data is accurately reconstructed. Please note that alternative embodiments can implement different ECC operations other than those described herein.

In some embodiments, in performing the ECC operation 308 on the codeword using the LLR output, at operation 205A, the processing logic updates an LLR field in an LLR mapper 306 with the LLR output, wherein the LLR field corresponds to the codeword. In some embodiments, the LLR mapper 306 is a metadata table (e.g., a lookup table). In some embodiments, the LLR mapper 306 is configured to store the LLR output values corresponding to each bit position within the LDPC codeword. In some embodiments, the LLR output values are indexed in the LLR mapper 306 by their specific identifiers or positions in the graph structure inherent to LDPC codes.

In some embodiment, in performing the ECC operation 308 on the codeword using the LLR output, at operation 205B, the processing logic retrieves the LLR output from the LLR mapper in performing the ECC operation on the codeword. In embodiments implementing an LDPC ECC operation, during the decoding process, an LDPC decoder accesses the LLR mapper 306 to obtain the initial LLRs (e.g., the LLR outputs), which represent the logarithmic probabilities of each bit being a '1' versus a '0'.

In some embodiments, in performing the ECC operation on the codeword using the LLR output, at operation 205C, the processing logic generates an ECC output in performing the ECC operation. In some embodiments, the ECC output is decoded or corrected data, which accurately represents the original information by fixing any errors introduced during transmission or storage.

In some embodiments, at operation 206, the processing logic trains the LLR estimator ML model 112. In some embodiments, the processing logic trains the LLR estimator ML model 112 using a stochastic gradient descent training model. Stochastic gradient descent (SGD) is an optimization algorithm used to train machine learning models by iteratively updating model parameters to minimize a loss function. SGD computes the gradient using a single training example at each iteration. In some embodiments, implementing the SGD training model involves initializing parameters, selecting a learning rate, and iteratively updating parameters based on the gradient calculated from individual or small batches of training samples. As part of the training operations, this process is repeated until convergence criteria are met or a maximum number of iterations is reached. In some embodiments, the processing logic trains the LLR estimator ML model 112 using historical sets of count values as training inputs and LLR outputs associated with respective historical count values as target outputs. In some embodiments, the processing logic performs training operations periodically. In some embodiments, ML models can be trained offline before integrating into the SSD drive. In some embodiments, ML models can be trained online before integrating into the SSD drive. In some embodiments, at operation 207, the processing logic re-trains the LLR estimator ML model 112 using the LLR output and the set of count values associated with the LLR output.

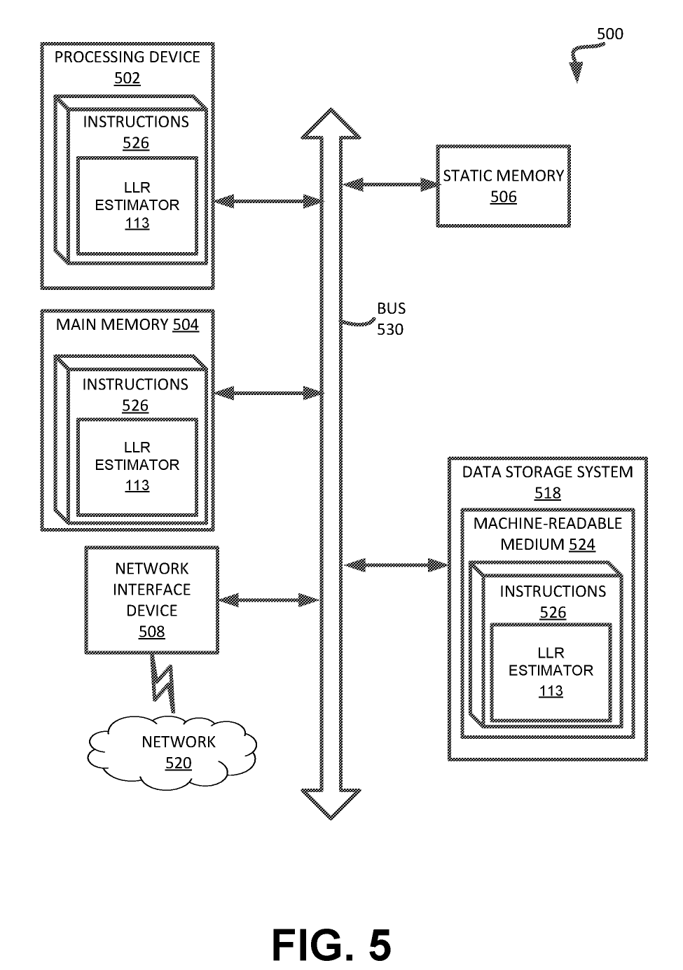

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the LLR estimator component 113 of FIG. 1). In alternative embodiments, the machine can be connected (e.g., networked) to other machines in a LAN, an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or RDRAM, etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to a LLR estimator component (e.g., the LLR estimator component 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system, comprising:
a memory device; and
a processing device, operatively coupled with the memory device, wherein the processing device is configured to perform operations comprising:
performing a read operation on the memory device to determine a codeword;
generating, from the read operation, a set of count values representing respective characteristics associated with the codeword;
providing the set of count values as an input to a log-likelihood ratio (LLR) estimator machine learning (ML) model;
receiving an output from the LLR estimator ML model, wherein the output comprises an LLR output corresponding to the codeword; and
performing an error correction code (ECC) operation on the codeword using the LLR output.

2. The system of claim 1, wherein generating the set of count values comprises:
updating a count of memory cells for a plurality of bins based on hard bit read information and soft bit read information corresponding to each memory cell and generated from the read operation.

3. The system of claim 1, wherein the ECC operation comprises a low density parity check (LDPC) operation.

4. The system of claim 1, wherein performing the ECC operation on the codeword using the LLR output comprises:
updating an LLR field in an LLR mapper with the LLR output, wherein the LLR field corresponds to the codeword;
retrieving the LLR output from the LLR mapper in performing the ECC operation on the codeword; and
generating an ECC output in performing the ECC operation.

5. The system of claim 4, wherein the LLR mapper comprises a metadata table.

6. The system of claim 1, wherein the LLR estimator ML model comprises a multi-layer neural network.

7. The system of claim 1, wherein the processing device is to perform operations further comprising:
training the LLR estimator ML model using a stochastic gradient descent training model.

8. The system of claim 1, wherein the processing device is to perform operations further comprising:
re-training the LLR estimator ML model using the LLR output and the set of count values associated with the LLR output.

9. A method comprising:
performing, by a processing device, a read operation on a memory device to determine a codeword;
generating, from the read operation, a set of count values representing respective characteristics associated with the codeword;
providing the set of count values as an input to a log-likelihood ratio (LLR) estimator machine learning (ML) model;
receiving an output from the LLR estimator ML model, wherein the output comprises an LLR output corresponding to the codeword; and
performing an error correction code (ECC) operation on the codeword using the LLR output.

10. The method of claim 9, wherein generating the set of count values comprises:
updating a count of memory cells for a plurality of bins based on hard bit read information and soft bit read information corresponding to each memory cell and generated from the read operation.

11. The method of claim 9, wherein the ECC operation comprises a low density parity check (LDPC) operation.

12. The method of claim 9, wherein performing the ECC operation on the codeword using the LLR output comprises:
updating an LLR field in an LLR mapper with the LLR output, wherein the LLR field corresponds to the codeword;
retrieving the LLR output from the LLR mapper in performing the ECC operation on the codeword; and
generating an ECC output in performing the ECC operation.

13. The method of claim 12, wherein the LLR mapper comprises a metadata table.

14. The method of claim 9, wherein the LLR estimator ML model comprises a multi-layer neural network.

15. The method of claim 9, wherein the processing device is to perform operations further comprising:
training the LLR estimator ML model using a stochastic gradient descent training model.

16. The method of claim 9, wherein the processing device is to perform operations further comprising:
re-training the LLR estimator ML model using the LLR output and the set of count values associated with the LLR output.

17. A non-transitory computer-readable storage medium comprising instructions that, when executed by a processing device, cause the processing device to perform operations comprising:
performing a read operation on a memory device to determine a codeword;
generating, from the read operation, a set of count values representing respective characteristics associated with the codeword;
providing the set of count values as an input to a log-likelihood ratio (LLR) estimator machine learning (ML) model;
receiving an output from the LLR estimator ML model, wherein the output comprises an LLR output corresponding to the codeword; and
performing an error correction code (ECC) operation on the codeword using the LLR output.

18. The non-transitory computer-readable storage medium of claim 17, wherein generating the set of count values comprises:
updating a count of memory cells for a plurality of bins based on hard bit read information and soft bit read information corresponding to each memory cell and generated from the read operation.

19. The non-transitory computer-readable storage medium of claim 17, wherein performing the ECC operation on the codeword using the LLR output comprises:
updating an LLR field in an LLR mapper with the LLR output, wherein the LLR field corresponds to the codeword;
retrieving the LLR output from the LLR mapper in performing the ECC operation on the codeword; and
generating an ECC output in performing the ECC operation.

20. The non-transitory computer-readable storage medium of claim 17, wherein the processing device is to perform operations further comprising:
training the LLR estimator ML model using a stochastic gradient descent training model.
